(19) United States
(12) Patent Application Publication
(10) Pub. No.: US 2025/0247061 A1
(43) Pub. Date: Jul. 31, 2025

(54) HARMONIC TERMINATION FOR DIFFERENTIAL AMPLIFIER

(71) Applicant: QUALCOMM Incorporated, San Diego, CA (US)

(72) Inventors: Zhenying LUO, Wayland, MA (US); Jing-Hwa CHEN, Sudbury, MA (US); Xinwei WANG, Dunstable, MA (US); Yan Kit Gary HAU, Westford, MA (US); Xiangdong ZHANG, Westford, MA (US)

(21) Appl. No.: 18/814,110

(22) Filed: Aug. 23, 2024

Related U.S. Application Data
(60) Provisional application No. 63/627,525, filed on Jan. 31, 2024.

(51) Int. Cl. H03F 3/24; H04B 1/04

(52) U.S. Cl. CPC H03F 3/245; H04B 1/0475; H03F 2200/294; H03F 2200/451; H04B 2001/0408

(57) ABSTRACT

Certain aspects of the present disclosure provide techniques for harmonic termination for a differential amplifier. An example apparatus comprises an amplifier configured to output a differential signal via a first output terminal and a second output terminal. The apparatus includes a resonant circuit coupled between the first output terminal and the second output terminal of the amplifier. The resonant circuit comprises a first capacitor, a second capacitor, a third capacitor, a first inductor, and a second inductor. The third capacitor is coupled between separate terminals of the inductors.

### CROSS-REFERENCE TO RELATED APPLICATION(S)

The present Application for Patent claims benefit of U.S. Provisional Application No. 63/627,525, filed Jan. 31, 2024, which is hereby expressly incorporated by reference herein in its entirety.

### INTRODUCTION

### Field of the Disclosure

Aspects of the present disclosure relate to wireless communications, and more particularly, to harmonic termination circuitry for an amplifier.

### Description of Related Art

Wireless communications systems are widely deployed to provide various telecommunication services such as telephony, video, data, messaging, broadcasts, etc. These wireless communications systems may employ multiple-access technologies capable of supporting communications with multiple users by sharing available wireless communications system resources with those users. Wireless communication devices may communicate RF signals via any of various suitable radio access technologies (RATs) including, but not limited to, 5G New Radio (NR), Evolved Universal Terrestrial Radio Access (E-UTRA), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., Institute of Electrical and Electronics Engineers (IEEE) 802.11 specifications), any future RAT, and/or the like.

In certain cases, a wireless communications device is equipped with a radio frequency (RF) transceiver (also referred to as an RF front-end) for communicating RF signals. In general, a baseband signal is modulated to convey information using a modulation technique, such as phase-shift keying (PSK) or any other suitable modulation technique. In a transmit mode, the RF transceiver is responsible for multiplexing the baseband signal with an RF carrier signal that is transmitted over the air (e.g., a wireless communication channel). Such an operation is called upconversion. In a receive mode, the RF transceiver converts a received RF signal to the baseband signal. Such an operation is called downconversion. The received baseband signal then can be demodulated into the information encoded at a transmitter. The RF transceiver may include a cascade of discrete components in a transmit chain and a receive chain, respectively. The cascade of components may include, for example, one or more of attenuators, switches, couplers, filters, mixers, amplifiers, frequency synthesizers, oscillators, antenna tuners, duplexers, diplexers, detectors, etc.

Although there have been great technological advancements in RF circuitry over many years, challenges still exist. For example, RF circuitry can still exhibit harmonic distortions. Accordingly, there is a continuous desire to improve the technical performance of RF circuitry, such as harmonic termination.

### SUMMARY

Some aspects provide an apparatus configured for wireless communications. The apparatus includes an amplifier configured to output a differential signal via a first output terminal and a second output terminal. The apparatus includes a resonant circuit coupled between the first output terminal and the second output terminal of the amplifier. The resonant circuit comprises a first capacitor having a first terminal and a second terminal, the first terminal of the first capacitor coupled to the first output terminal of the amplifier, the second terminal of the first capacitor coupled to a first node; a second capacitor having a third terminal and a fourth terminal, the third terminal of the second capacitor coupled to the second output terminal of the amplifier, the fourth terminal of the second capacitor coupled to a second node; a first inductor having a fifth terminal and a sixth terminal, the fifth terminal of the first inductor coupled to the first node; a second inductor having a seventh terminal and an eighth terminal, the seventh terminal of the second inductor coupled to the second node; and a third capacitor coupled between the first node and the second node.

Some aspects provide a method for harmonic termination control of an amplifier. The method includes outputting an amplified differential signal via a first output terminal and a second output terminal of an amplifier. The method includes controlling harmonic termination of the differential signal using a resonant circuit coupled between the first output terminal and the second output terminal of the amplifier. The resonant circuit comprises a first capacitor having a first terminal and a second terminal, the first terminal of the first capacitor coupled to the first output terminal of the amplifier, the second terminal of the first capacitor coupled to a first node; a second capacitor having a third terminal and a fourth terminal, the third terminal of the second capacitor coupled to the second output terminal of the amplifier, the fourth terminal of the second capacitor coupled to a second node; a first inductor having a fifth terminal and a sixth terminal, the fifth terminal of the first inductor coupled to the first node; a second inductor having a seventh terminal and an eighth terminal, the seventh terminal of the second inductor coupled to the second node; and a third capacitor coupled between the first node and the second node.

Some aspects provide a transceiver. The transceiver comprises a transmit chain configured to output a radio frequency signal for transmission. The transmit chain comprises: an amplifier configured to output a differential signal via a first output terminal and a second output terminal; and a resonant circuit coupled between the first output terminal and the second output terminal of the amplifier. The resonant circuit comprises: a first capacitor having a first terminal and a second terminal, the first terminal of the first capacitor coupled to the first output terminal of the amplifier, the second terminal of the first capacitor coupled to a first node; a second capacitor having a third terminal and a fourth terminal, the third terminal of the second capacitor coupled to the second output terminal of the amplifier, the fourth terminal of the second capacitor coupled to a second node; a first inductor having a fifth terminal and a sixth terminal, the fifth terminal of the first inductor coupled to the first node; a second inductor having a seventh terminal and an eighth terminal, the seventh terminal of the second inductor coupled to the second node; and a third capacitor coupled between the first node and the second node.

Other aspects provide: an apparatus operable, configured, or otherwise adapted to perform any one or more of the aforementioned methods and/or those described elsewhere herein; a non-transitory, computer-readable medium comprising instructions that, when executed by a processor of an apparatus, cause the apparatus to perform the aforementioned methods as well as those described elsewhere herein; a computer program product embodied on a computer-readable storage medium comprising code for performing the aforementioned methods as well as those described elsewhere herein; and/or an apparatus comprising means for performing the aforementioned methods as well as those described elsewhere herein. By way of example, an apparatus may comprise a processing system, a device with a processing system, or processing systems cooperating over one or more networks.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the drawings. It is to be noted, however, that the appended drawings illustrate only certain typical aspects of this disclosure and are therefore not to be considered limiting of its scope, for the description may admit to other equally effective aspects.

FIG. 1 illustrates an example wireless communications system.

FIG. 2 illustrates an example wireless communication device communicating with another device.

FIG. 3A illustrates an example amplifier circuit having harmonic termination control for multiple harmonics.

FIG. 3B illustrates another example amplifier circuit having harmonic termination control for multiple harmonics.

FIG. 4A illustrates an example circuit model of the amplifier circuit depicted in FIG. 3 for an even mode excitation signal.

FIG. 4B illustrates an example circuit model of the amplifier circuit depicted in FIG. 3 for an odd mode excitation signal.

FIG. 5A illustrates another example amplifier circuit having harmonic termination control for multiple harmonics.

FIG. 5B illustrates another example amplifier circuit having harmonic termination control for multiple harmonics.

FIG. 6A illustrates another example amplifier circuit having harmonic termination control for multiple harmonics.

FIG. 6B illustrates another example amplifier circuit having harmonic termination control for multiple harmonics.

FIG. 7 illustrates example operations for harmonic termination control of an amplifier.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

Aspects of the present disclosure provide apparatus and techniques for harmonic termination for a differential amplifier.

In certain aspects, an RF transmitter may use a power amplifier (PA) to amplify a signal for transmission via an antenna. For example, the PA may convert a low-power RF signal into a higher power RF signal, and the output of the power amplifier may drive the antenna to emit RF energy for wireless communications. The output of the PA may have certain harmonic distortions, including a second harmonic and/or a third harmonic, for example, due to non-linear characteristics associated with the PA and/or other circuitry (e.g., a mixer) in a transmit chain of the transmitter. The harmonic distortions may affect the performance of the PA, such as adjacent channel leakage ratio (ACLR), error vector magnitude (EVM), power output, etc.

Technical problems for certain amplifiers (such as a differential PA) include, for example, applying effective harmonic termination to control certain harmonics in the amplifier output. In certain cases, a resonant circuit may be arranged between the differential output terminals of an amplifier to control the harmonic distortion exhibited in the output. An example resonant circuit may consist of two capacitors coupled in series between the output terminals of the amplifier and an inductor having a terminal coupled between the two capacitors. With this inductor-capacitor (LC) architecture, the resonant circuit is capable of controlling a second harmonic in the differential signal. For example, the resonant circuit may be capable of suppressing the second harmonic in the differential signal. However, in some cases, a third harmonic may be exhibited in the amplifier output, and thus, the resonant circuit may be incapable of controlling the harmonic termination of the second harmonic and the third harmonic.

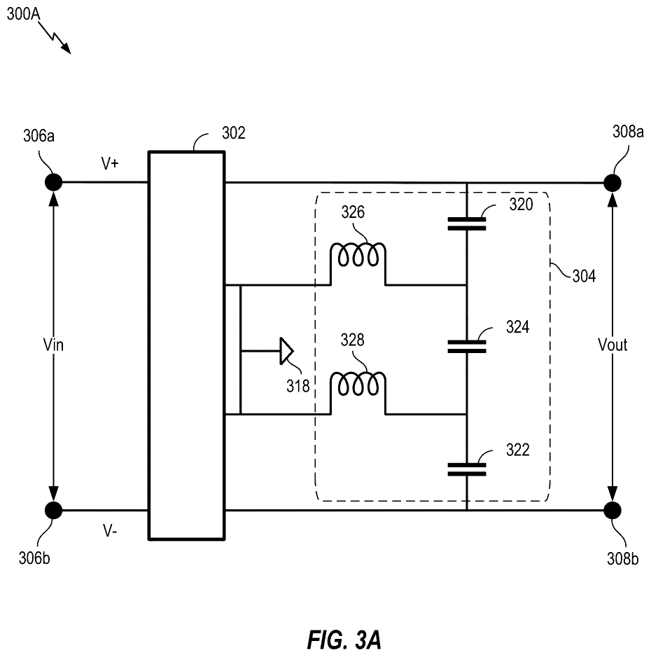

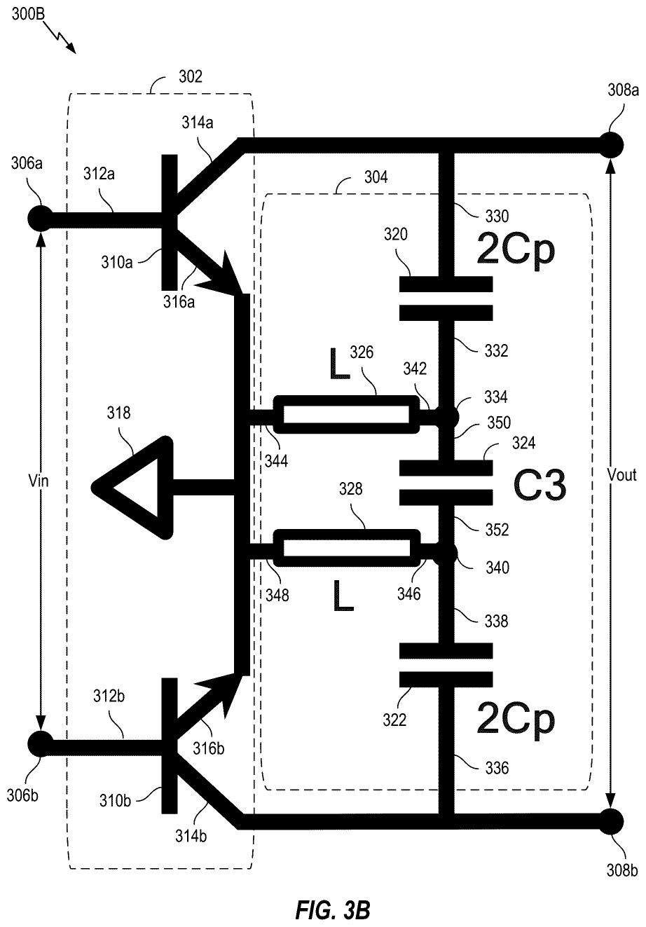

Aspects described herein may overcome the aforementioned technical problem(s), for example, by providing an enhanced resonant circuit configured to control harmonic termination for a second harmonic and a third harmonic in an amplifier output. As an example, the resonant circuit may include at least a first capacitor, a second capacitor, a third capacitor, a first inductor, and a second inductor. The third capacitor may be coupled between the inductors and the other capacitors. The third capacitor may be tuned to suppress the third harmonic in the amplifier output. The resonant circuit may employ various LC architectures as further described herein with respect to FIGS. 3, 5A, 5B, 6A, and 6B.

Certain circuitry for harmonic termination described herein may provide various beneficial technical effects and/or advantages. The circuitry for harmonic termination may enable improved amplifier performance, such as reduced ACLR, reduced EVM, and/or increased power-added efficiency (PAE). The improved amplifier performance may be attributable to the harmonic termination described herein that allows for suppression of a second harmonic and a third harmonic in the output signal of the amplifier.

### Example Wireless Communications System

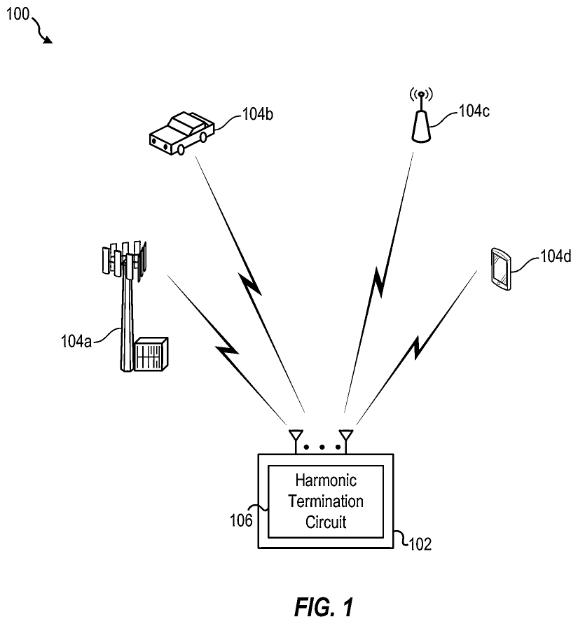

FIG. 1 illustrates an example wireless communications system 100 in which aspects of the present disclosure may be performed. For example, the wireless communications system 100 may include a wireless wide area network (WWAN) and/or a wireless local area network (WLAN). For example, a WWAN may include a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation (2G) or Third Generation (3G) network), a code division multiple access (CDMA) system (e.g., a 2G/3G network), any future WWAN system, or any combination thereof. A WLAN may include a wireless network configured for communications according to an Institute of Electrical and Electronics Engineers (IEEE) standard such as one or more of the 802.11 standards, etc. In some cases, the wireless communications system 100 may include a device-to-device (D2D) communications network or a short-range communications system, such as Bluetooth communications.

As illustrated in FIG. 1, the wireless communications system 100 may include a first wireless device 102 communicating with any of various second wireless devices 104a-d (hereinafter “the second wireless device 104”) via any of various radio access technologies (RATs), where a wireless device may refer to a wireless communications device. The RATs may include, for example, WWAN communications (e.g., E-UTRA and/or 5G NR), WLAN communications (e.g., IEEE 802.11), vehicle-to-everything (V2X) communications, non-terrestrial network (NTN) communications, short-range communications (e.g., Bluetooth), etc.

The first wireless device 102 may include any of various wireless communications devices including a user equipment (UE), a base station, a wireless station, an access point, customer-premises equipment (CPE), etc. In certain aspects, the first wireless device 102 includes a harmonic termination circuit 106 that controls the harmonic termination associated with an amplifier, in accordance with aspects of the present disclosure.

The second wireless device 104 may include, for example, a base station 104a, a vehicle 104b, an access point (AP) 104c, and/or a UE 104d. Further, the wireless communications systems 100 may include terrestrial aspects, such as ground-based network entities (e.g., the base station 104a and/or access point 104c), and/or non-terrestrial aspects, such as a spaceborne platform and/or an aerial platform, which may include network entities on-board (e.g., one or more base stations) capable of communicating with other network elements (e.g., terrestrial base stations) and/or user equipment.

The base station 104a may generally include: a NodeB, enhanced NodeB (eNB), next generation enhanced NodeB (ng-eNB), next generation NodeB (gNB or gNodeB), access point, base transceiver station, radio base station, radio transceiver, transceiver function, transmission reception point, and/or others. The base station 104a may provide communications coverage for a respective geographic coverage area, which may sometimes be referred to as a cell, and which may overlap in some cases (e.g., a small cell may have a coverage area that overlaps the coverage area of a macro cell). A base station may, for example, provide communications coverage for a macro cell (covering relatively large geographic area), a pico cell (covering relatively smaller geographic area, such as a sports stadium), a femto cell (relatively smaller geographic area (e.g., a home)), and/or other types of cells.

The first wireless device 102 and/or the UE 104d may generally include: a cellular phone, smart phone, session initiation protocol (SIP) phone, laptop, personal digital assistant (PDA), satellite radio, global positioning system, multimedia device, video device, digital audio player, camera, game console, tablet, smart device, wearable device, vehicle, electric meter, gas pump, large or small kitchen appliance, healthcare device, implant, sensor/actuator, display, internet of things (IoT) devices, always on (AON) devices, edge processing devices, or other similar devices. A UE may also be referred to more generally as a mobile device, a wireless device, a wireless communications device, a wireless station (STA), a mobile station, a subscriber station, a mobile subscriber station, a mobile unit, a subscriber unit, a wireless unit, a remote unit, a remote device, an access terminal, a mobile terminal, a wireless terminal, a remote terminal, a handset, and other terms.

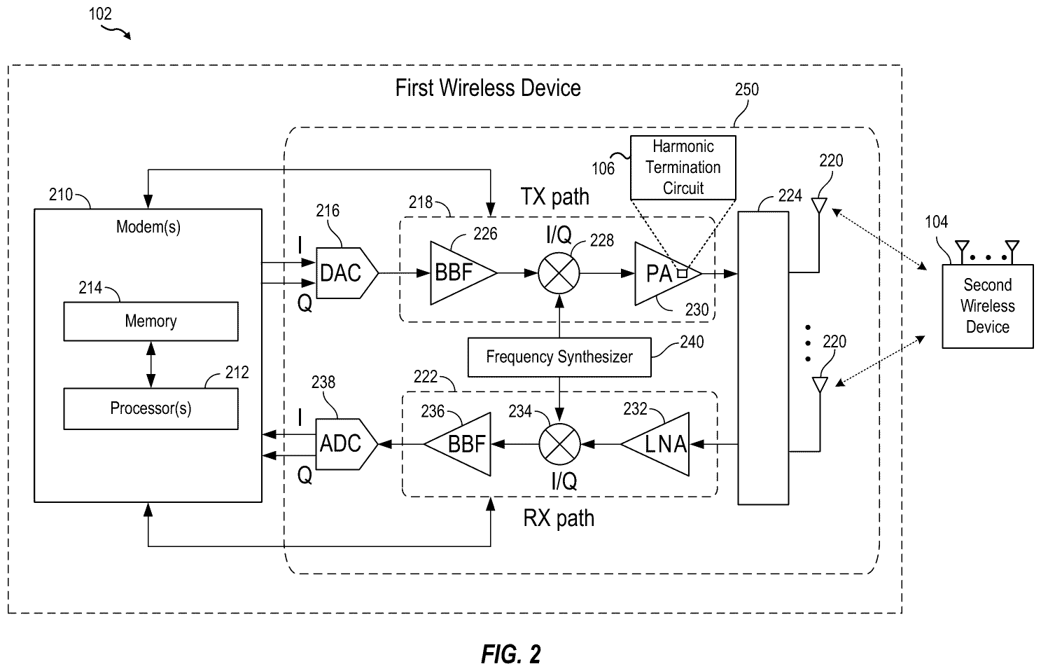

FIG. 2 illustrates example components of the first wireless device 102, which may be used to communicate with any of the second wireless devices 104.

The first wireless device 102 may be, or may include, a chip, system on chip (SoC), system in package (SiP), chipset, package, device that includes one or more modems 210 (hereinafter “the modem 210”). In some cases, the modem 210 may include, for example, any of a WWAN modem (e.g., a modem configured to communicate via E-UTRA 5G NR, and/or any future WWAN communications standards), a WLAN modem (e.g., a modem configured to communicate via IEEE 802.11 standards), a Bluetooth modem, a NTN modem, etc. In certain aspects, the first wireless device 102 also includes one or more RF transceivers (hereinafter “the RF transceiver 250”). In some cases, the RF transceiver 250 may be referred to as an RF front end (RFFE). In some aspects, the modem 210 further includes one or more processors, processing blocks or processing elements (hereinafter “the processor 212”) and one or more memory blocks or elements (hereinafter “the memory 214”).

In certain aspects, the processor 212 may process any of certain protocol stack layers associated with a radio access technology (RAT). For example, the processor 212 may process any of an application layer, packet layer, WLAN protocol stack layers (e.g., a link or a medium access control (MAC) layer), and/or WWAN protocol stack layers (e.g., a radio resource control (RRC) layer, a packet data convergence protocol (PDCP) layer, a radio link control (RLC) layer, and a MAC layer).

The modem 210 may generally be configured to implement a physical (PHY) layer. For example, the modem 210 may be configured to modulate packets and to output the modulated packets to the RF transceiver 250 for transmission over a wireless medium. The modem 210 is similarly configured to obtain modulated packets received by the RF transceiver 250 and to demodulate the packets to provide demodulated packets. In addition to a modulator and a demodulator, the modem 210 may further include digital signal processing (DSP) circuitry, automatic gain control (AGC), a coder, a decoder, a multiplexer, and/or a demultiplexer (not shown).

As an example, while in a transmission mode, the modem 210 may obtain data from a data source, such as an application processor. The data may be provided to a coder, which encodes the data to provide encoded bits. The encoded bits may be mapped to points in a modulation constellation (e.g., using a selected modulation and coding scheme) to provide modulated symbols. The modulated symbols may be mapped, for example, to spatial stream(s) or space-time streams. The modulated symbols may be multiplexed, transformed via an inverse fast Fourier transform (IFFT) block, and subsequently provided to DSP circuitry for transmit windowing and filtering. The digital signals may be provided to a digital-to-analog converter (DAC) 216. In certain aspects involving beamforming, the modulated symbols in the respective spatial streams may be precoded via a steering matrix prior to provision to the IFFT block.

The modem 210 may be coupled to the RF transceiver 250 including a transmit (TX) path 218 (also known as a transmit chain) for transmitting signals via one or more antennas 220 (hereinafter “the antenna 220”) and a receive (RX) path 222 (also known as a receive chain) for receiving signals via the antennas 220. When the TX path 218 and the RX path 222 share the antenna 220, the paths may be coupled to the antenna 220 via an interface 224, which may include any of various suitable RF devices, such as an antenna tuner, a switch, a duplexer, a diplexer, a multiplexer, and the like. As an example, the modem 210 may output digital in-phase (I) and/or quadrature (Q) baseband signals representative of the respective symbols to the DAC 216.

Receiving I or Q baseband analog signals from the DAC 216, the TX path 218 may include a baseband filter (BBF) 226, a mixer 228 (which may include one or several mixers), and a power amplifier (PA) 230. The BBF 226 filters the baseband signals received from the DAC 216, and the mixer 227 mixes the filtered baseband signals with a transmit local oscillator (LO) signal to convert the baseband signal to a different frequency (e.g., upconvert from baseband to a radio frequency). In some aspects, the frequency conversion process produces the sum and difference frequencies between the LO frequency and the frequencies of the baseband signal. The sum and difference frequencies are referred to as the beat frequencies. Some beat frequencies are in the RF range, such that the signals output by the mixer 228 are typically RF signals, which may be amplified by the PA 230 before transmission by the antenna 220. In certain aspects, the PA 230 includes the harmonic termination circuit 106 that controls the harmonic termination of the PA output as further described herein with respect to FIGS. 3-7. The antennas 220 may emit RF signals, which may be received at the second wireless device 104. While one mixer 228 is illustrated, several mixers may be used to upconvert the filtered baseband signals to one or more intermediate frequencies and to thereafter upconvert the intermediate frequency signals to a frequency for transmission.

The RX path 222 may include a low noise amplifier (LNA) 232, a mixer 234 (which may include one or several mixers), and a baseband filter (BBF) 236. RF signals received via the antenna 220 (e.g., from the second wireless device 104) may be amplified by the LNA 232, and the mixer 234 mixes the amplified RF signals with a receive local oscillator (LO) signal to convert the RF signal to a baseband frequency (e.g., downconvert). The baseband signals output by the mixer 234 may be filtered by the BBF 236 before being converted by an analog-to-digital converter (ADC) 238 to digital I or Q signals for digital signal processing. The modem 210 may receive the digital I or Q signals and further process the digital signals, for example, demodulating the digital signals into information.

Certain transceivers may employ frequency synthesizers with a voltage-controlled oscillator (VCO) to generate a stable, tunable LO frequency with a particular tuning range. Thus, the transmit LO frequency may be produced by a frequency synthesizer 240, which may be buffered or amplified by an amplifier (not shown) before being mixed with the baseband signals in the mixer 228. Similarly, the receive LO frequency may be produced by the frequency synthesizer 240, which may be buffered or amplified by an amplifier (not shown) before being mixed with the RF signals in the mixer 234. Separate frequency synthesizers may be used for the TX path 218 and the RX path 222.

While in a reception mode, the modem 210 may obtain digitally converted signals via the ADC 238 and RX path 222. As an example, in the modem 210, digital signals may be provided to the DSP circuitry, which is configured to acquire a received signal, for example, by detecting the presence of the signal and estimating the initial timing and frequency offsets. The DSP circuitry is further configured to digitally condition the digital signals, for example, using channel (narrowband) filtering, analog impairment conditioning (such as correcting for I/Q imbalance), and applying digital gain to ultimately obtain a narrowband signal. The output of the DSP circuitry may be fed to the AGC, which is configured to use information extracted from the digital signals, for example, in one or more received training fields, to determine an appropriate gain. The output of the DSP circuitry also may be coupled with the demodulator, which is configured to extract modulated symbols from the signal and, for example, compute the logarithm likelihood ratios (LLRs) for each bit position of each subcarrier in each spatial stream. The demodulator may be coupled with the decoder, which may be configured to process the LLRs to provide decoded bits. The decoded bits from all of the spatial streams may be fed to the demultiplexer for demultiplexing. The demultiplexed bits may be descrambled and provided to a medium access control layer (e.g., the processor 212) for processing, evaluation, or interpretation.

The modem 210 and/or processor 212 may control the transmission of signals via the TX path 218 and/or reception of signals via the RX path 222. In some aspects, the modem 210 and/or processor 212 may be configured to perform various operations, such as those associated with any of the methods described herein. The modem 210 and/or processor 212 may include a microcontroller, a microprocessor, an application processor, a baseband processor, a MAC processor, an artificial intelligence processor, a digital signal processor (DSP), an application specific integrated circuit (ASIC), a field programmable gate array (FPGA) or other programmable logic device (PLD), discrete gate or transistor logic, discrete hardware components, or any combination thereof. The memory 214 may store data and program codes (e.g., processor-readable instructions) for performing wireless communications as described herein. In some cases, the memory 214 may be external to the modem 210 and/or processor 212 and/or incorporated therein (as illustrated).

FIG. 2 shows an example transceiver design. It will be appreciated that other transceiver designs or architectures may be applied in connection with aspects of the present disclosure. For example, while examples discussed herein utilize I and Q signals (e.g., quadrature modulation), those of skill in the art will understand that components of the transceiver may be configured to utilize any other suitable modulation, such as polar modulation. As another example, circuit blocks may be arranged differently from the configuration shown in FIG. 2, and/or other circuit blocks not shown in FIG. 2 may be implemented in addition to or instead of the blocks depicted.

### Example Harmonic Termination for a Differential Amplifier

Aspects of the present disclosure provide circuitry for harmonic termination control of a differential amplifier. The harmonic termination circuitry described herein may enable improved amplifier performance, such as reduced ACLR, reduced EVM, and/or increased PAE.

FIG. 3A illustrates an example amplifier circuit 300A having harmonic termination control for multiple harmonics. In this example, the amplifier circuit 300A comprises an amplifier 302 and a resonant circuit 304. The amplifier circuit 300A may be employed in RF circuitry including, for example, a power amplifier (e.g., the PA 230), a transmit chain (e.g., the TX path 218) of a transceiver (e.g., the RF transceiver 250), and/or any other suitable amplifier (e.g., the LNA 232). As an example, a transceiver may include a transmit chain with the amplifier circuit 300A. The transmit chain may be configured to output an RF signal for transmission.

The amplifier 302 may be or include a linear power amplifier, such as a Class A power amplifier and/or a Class AB power amplifier. The amplifier 302 may be or include a differential amplifier having differential input terminals 306a-b and differential output terminals 308a-b. The amplifier may be configured to obtain a differential input signal, amplify the input signal (e.g., convert the input signal to a higher power), and output an amplified, differential signal via the first output terminal 308a and the second output terminal 308b. The amplifier 302 may include a variety of different gain element(s), such as one or more transistors. As an example, the amplifier 302 may include a transistor configuration that may provide a differential output, as further described herein with respect to FIG. 3B.

The resonant circuit 304 may be coupled between the first output terminal 308a and the second output terminal 308b of the amplifier 302. The resonant circuit 304 and the amplifier 302 may be coupled to a reference node 318, as further described herein with respect to FIG. 3B. The resonant circuit 304 may be tuned to control the harmonic termination of the differential signal, which is output via the amplifier 302. For example, the resonant circuit 304 may be configured to suppress one or more harmonics (e.g., a second harmonic and/or a third harmonic) in the differential signal. The resonant circuit 304 may be or include a tank circuit, an inductor-capacitor (LC) circuit, a resistor-inductor-capacitor (RLC) circuit, etc. In this example, the resonant circuit 304 comprises a first capacitor 320, a second capacitor 322, a third capacitor 324, a first inductor 326, and a second inductor 328. In certain aspects, any of the capacitors 320, 322, 324 may be or include one or more capacitive elements, such as a tantalum capacitor, aluminum capacitor, ceramic capacitor, varactor, a metal-insulator-metal (MIM) capacitor, metal-oxide-metal (MOM) capacitor, a metal-oxide-semiconductor (MOS) capacitor, a metal fringe capacitor, a trench capacitor, a junction capacitance of a diode or transistor, or the like. Any of the inductors 326, 328 may be formed from a metal or conductive spiral, for example, including circular spiral structure, an octagonal spiral structure, a symmetric spiral structure, stacked spiral structure, parallel spirals, or the like.

FIG. 3B illustrates an example amplifier circuit 300B having harmonic termination control for multiple harmonics. In this example, the amplifier circuit 300B may be an example of the amplifier circuit 300A, and accordingly shows shared components of the amplifier circuit 300A. The amplifier 302 may include a first transistor 310a and a second transistor 310b. In certain aspects, each of the transistors 310a-b may be or include a bipolar junction transistor (BJT), a heterojunction bipolar transistor (HBT), a field effect transistor (FET), and/or a high electron mobility transistor (HEMT).

Each of the input terminals 306a-b of the amplifier 302 may correspond to a base 312a-b of a respective transistor 310a-b, and each of the output terminals 308a-b of the amplifier may correspond to a collector 314a-b of a respective transistor 310a-b. The first input terminal 306a of the amplifier 302 corresponds to or is coupled to a first base 312a of the first transistor 310a, and the second input terminal 306b of the amplifier 302 corresponds to or is coupled to a second base 312b of the second transistor 310b. The first output terminal 308a of the amplifier 302 corresponds to or is coupled to a first collector 314a of the first transistor 310a, and the second output terminal 308b corresponds to or is coupled to a second collector 314b of the second transistor 310b. A first emitter 316a of the first transistor 310a is coupled to the reference node 318 (e.g., a reference potential or signal ground node), and a second emitter 316b of the second transistor 310b is coupled to the reference node 318.

A first terminal 330 of the first capacitor 320 is coupled to the first output terminal 308a of the amplifier 302, and a second terminal 332 of the first capacitor 320 is coupled to a first node 334. A third terminal 336 of the second capacitor 322 is coupled to the second output terminal 308b of the amplifier 302, and a fourth terminal 338 of the second capacitor 322 is coupled to a second node 340. A fifth terminal 342 of the first inductor 326 is coupled to the first node 334, and a sixth terminal 344 of the first inductor 326 is coupled to the reference node 318. A seventh terminal 346 of the second inductor 328 is coupled to the second node 340, and an eighth terminal 348 of the second inductor 328 is coupled to the reference node 318. The third capacitor 324 is coupled between the first node 334 and the second node 340. Accordingly, in certain aspects, the third capacitor 324 is coupled between the first inductor 326 and the second inductor 328. As an example, a ninth terminal 350 of the third capacitor 324 is coupled to the first node 334, and a tenth terminal 352 of the third capacitor 324 is coupled to the second node 340.

In certain aspects, the first capacitor 320 and the second capacitor 322 may have symmetric capacitances. For example, the first capacitor 320 has a first capacitance value, and the second capacitor 322 has a second capacitance value. The first capacitance value and the second capacitance value may be within a threshold of one another (e.g., ±10% of a target value). The first capacitance value and the second capacitance value may be tuned or selected to control or match an impedance at a fundamental frequency associated with or in the differential signal, such as a carrier frequency. In certain aspects, based on the value of the first capacitance value and the second capacitance value, the inductance values of the inductors 326, 328 may be tuned or selected to control or suppress the second harmonic in the differential signal or allow the second harmonic to pass through the resonant circuit 304. The inductance values of the inductors 326, 328 may be within a threshold of one another (e.g., ±10% of a target value). The third capacitor 324 has a capacitance value tuned or selected to control at least a third harmonic associated with or in the differential signal. For example, the resonant circuit 304 may have an impedance at the third harmonic that is configured to suppress or attenuate the third harmonic or allow the third harmonic to remain in the differential signal (for example, as a bandpass filter or bandstop filter at the third harmonic). In certain aspects, the resonant circuit 304 may have an impedance at the second harmonic that is configured to suppress or attenuate the second harmonic or allow the second harmonic to remain in the differential signal (for example, as a bandpass filter or bandstop filter at the second harmonic). Accordingly, the multi-harmonic termination of the resonant circuit 304 may enable improved amplifier performance, such as reduced ACLR, reduced EVM, and/or increased PAE.

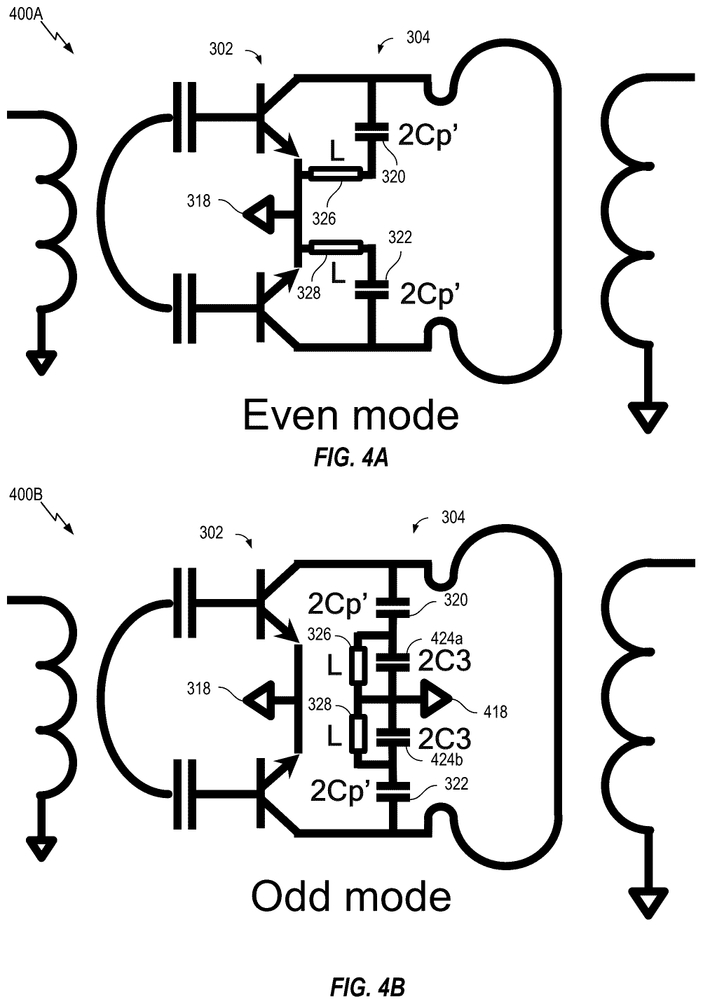

FIGS. 4A and 4B illustrate example circuit models 400A, 400B of the amplifier circuit depicted in FIG. 3 for an even mode excitation and an odd mode excitation, respectively. The circuit models 400A, 400B are conceptualized views of how the amplifier circuit 300A, 300B may operate in the even mode and odd mode, respectively, and thus, the circuit models 400A, 400B are not illustrative of actual physical hardware. The components illustrated in the circuit models 400A, 400B correspond to the same components in FIG. 3.

Referring to FIG. 4A, in the even mode (e.g., when the voltages of the differential input signals are equal), the third capacitor 324 is effectively transparent due to the symmetry of the input excitation. Accordingly, the first capacitor 320, second capacitor 322, and the inductors 326, 328 control the harmonic termination (e.g., the second harmonic termination) in the even mode.

As shown in FIG. 4B, in the odd mode (e.g., when the voltages of the differential input signals have opposite polarities), there is a virtual ground 418 at the midplane of the circuit model 400B. Accordingly, the third capacitor is effectively split into separate virtual capacitors 424a-b, and the virtual capacitors 424a-b and the inductors 326, 328 are tuned to control the harmonic termination of the third harmonic in the odd mode. For example, the virtual capacitors 424a-b and the inductors 326, 328 may resonate with the inductors 426, 428 to control the harmonic termination of the third harmonic.

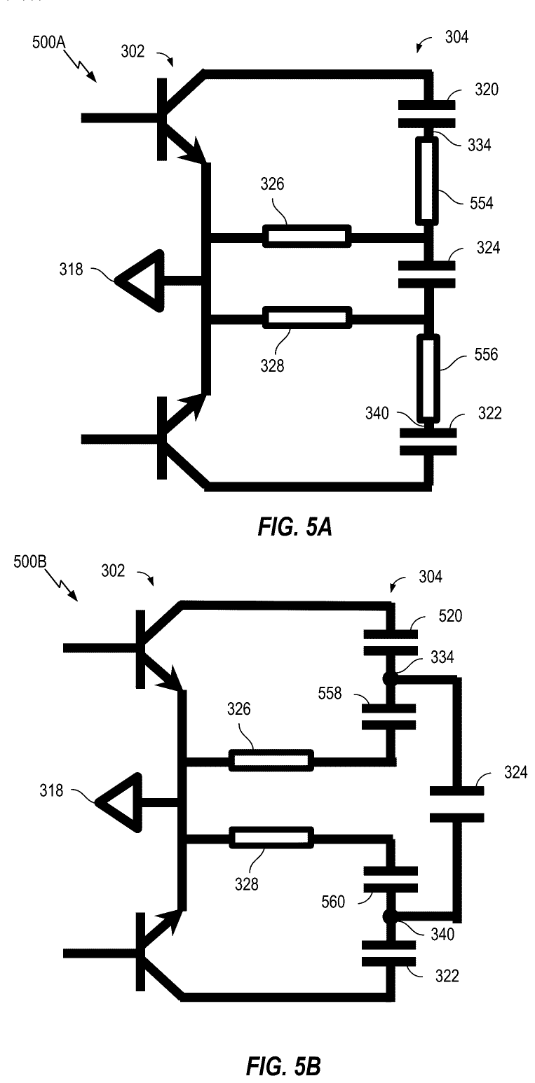

FIG. 5A illustrates another example amplifier circuit 500A having harmonic termination control for multiple harmonics. In this example, the amplifier circuit 500A is similar to the amplifier circuit 300A, 300B, and accordingly shows shared components of the amplifier circuit 300A, 300B. However, the amplifier circuit 500A further includes a third inductor 554 and a fourth inductor 556. The third inductor 554 may be coupled between the first node 534 and the third capacitor 324, and the fourth inductor 556 may be coupled between the second node 340 and the third capacitor 324. That is, the first inductor 326 and the third capacitor 324 may be coupled to the first node 334 via the third inductor 554, and the second inductor 328 and the third capacitor 324 may be coupled to the second node 340 via the fourth inductor 556.

FIG. 5B illustrates another example amplifier circuit 500B having harmonic termination control for multiple harmonics. In this example, the amplifier circuit 500B is similar to the amplifier circuit 300B, and accordingly shows shared components of the amplifier circuit 300B. However, the amplifier circuit 500B further includes a fourth capacitor 558 and a fifth capacitor 560. The fourth capacitor 558 may be coupled between the first inductor 326 and the first node 334, and the fifth capacitor 560 may be coupled between the second inductor 328 and the second node 340.

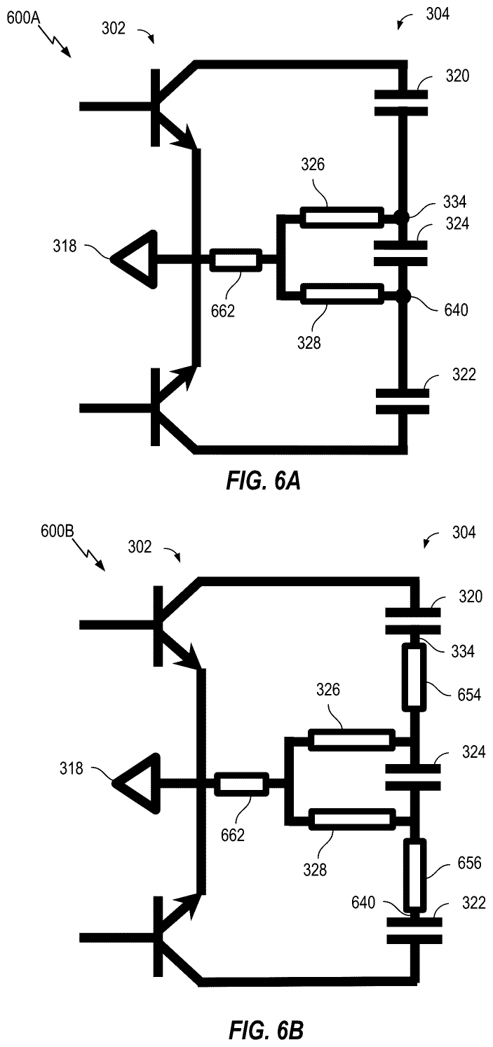

FIG. 6A illustrates another example amplifier circuit 600A having harmonic termination control for multiple harmonics. In this example, the amplifier circuit 600A is similar to the amplifier circuit 300B, and accordingly shows shared components of the amplifier circuit 300B. However, the amplifier circuit 600A further includes a fifth inductor 662 coupled between the reference node 318 and the other inductors 326, 328.

FIG. 6B illustrates another example amplifier circuit 600B having harmonic termination control for multiple harmonics. In this example, the amplifier circuit 600B is similar to the amplifier circuit 300B, and accordingly shows shared components of the amplifier circuit 300B. However, the amplifier circuit 600B further includes a third inductor 654, a fourth inductor 656, and a fifth inductor 662. The third inductor 654 is coupled between the first node 334 and the third capacitor 324, and the fourth inductor 656 is coupled between the second node 340 and the third capacitor 324. The fifth inductor 662 is coupled between the reference node 318 and the other inductors 326, 328. In some cases, the amplifier circuit 600B may be considered a type of combination of the amplifier circuits 500A, 600A of FIGS. 5A and 6A.

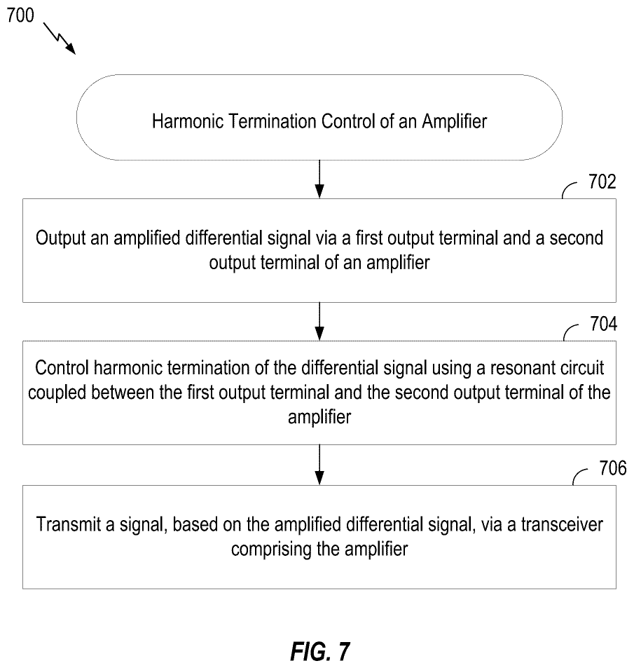

FIG. 7 illustrates example operations 700 for harmonic termination control of an amplifier. The operations 700 may be performed, for example, by an amplifier circuit, such as the amplifier circuit 300A, 300B, 500A, 500B, 600A, or 600B. In certain aspects, the amplifier circuit may be included in a transceiver, such as the RF transceiver 250 of FIG. 2.

The operations 700 may optionally begin, at block 702, where the amplifier circuit outputs an amplified differential signal via a first output terminal and a second output terminal of an amplifier

At block 704, the amplifier circuit controls harmonic termination of the differential signal using a resonant circuit coupled between the first output terminal and the second output terminal of the amplifier. The resonant circuit may be or include any of the resonant circuits described herein with respect to FIGS. 3, 5A, 5B, 6A, and 6B. To control the harmonic termination, the amplifier circuit may suppress (e.g., attenuate) one or more harmonics in the differential signal using the resonant circuit. In certain aspects, to control the harmonic termination, the amplifier circuit may allow a harmonic (e.g., a second harmonic) to pass through the resonant circuit. The one or more harmonics may comprise one or more of a second harmonic or a third harmonic of a fundamental frequency in the differential signal. The fundamental frequency may include a carrier frequency, for example.

At block 706, the transceiver (e.g., the RF transceiver 250) may transmit a signal, based on the amplified differential signal (e.g., a single ended signal), where the transceiver comprises the amplifier. As an example, the transceiver may transmit the signal to another wireless communication device (e.g., any of the second wireless devices 104 depicted in FIG. 1). The signal may indicate (or carry) any of various information, such as data and/or control information.

Aspects of the present disclosure may be applied to any of various wireless communication devices that may perform signal amplification using an amplifier with harmonic termination described herein.

### Example Aspects

Implementation examples are described in the following numbered clauses:
Aspect 1: An apparatus configured for wireless communications, comprising: an amplifier configured to output a differential signal via a first output terminal and a second output terminal; and a resonant circuit coupled between the first output terminal and the second output terminal of the amplifier, the resonant circuit comprising: a first capacitor having a first terminal and a second terminal, the first terminal of the first capacitor being coupled to the first output terminal of the amplifier, the second terminal of the first capacitor being coupled to a first node; a second capacitor having a third terminal and a fourth terminal, the third terminal of the second capacitor being coupled to the second output terminal of the amplifier, the fourth terminal of the second capacitor being coupled to a second node; a first inductor having a fifth terminal and a sixth terminal, the fifth terminal of the first inductor being coupled to the first node; a second inductor having a seventh terminal and an eighth terminal, the seventh terminal of the second inductor being coupled to the second node; and a third capacitor coupled between the first node and the second node.
Aspect 2: The apparatus of Aspect 1, wherein the resonant circuit is configured to control an impedance of the resonant circuit at one or more harmonics in the differential signal.
Aspect 3: The apparatus of Aspect 2, wherein the one or more harmonics comprise one or more of a second harmonic or a third harmonic.
Aspect 4: The apparatus according to any of Aspects 1-3, wherein: the first capacitor has first capacitance value; the second capacitor has a second capacitance value; and the first capacitance value and the second capacitance value are within a threshold of one another.
Aspect 5: The apparatus of Aspect 4, wherein the first capacitance value and the second capacitance value are tuned to control an impedance of the resonant circuit at a fundamental frequency associated with the differential signal.
Aspect 6: The apparatus according to any of Aspects 1-5, wherein the third capacitor comprises a ninth terminal and a tenth terminal, the ninth terminal of the third capacitor being coupled to the first node, and the tenth terminal of the third capacitor being coupled to the second node.
Aspect 7: The apparatus according to any of Aspects 1-6, wherein the third capacitor has a capacitance value tuned to control an impedance of the resonant circuit at a third harmonic associated with the differential signal.
Aspect 8: The apparatus of Aspect 6 or 7, wherein: the fifth terminal of the first inductor is coupled to the ninth terminal of the third capacitor and the second terminal of the first capacitor; the sixth terminal of the first inductor is coupled to a reference node; the seventh terminal of the second inductor is coupled to the tenth terminal of the third capacitor and the fourth terminal of the second capacitor; and the eighth terminal of the second inductor is coupled to the reference node.
Aspect 9: The apparatus of Aspect 8, wherein the amplifier comprises: a first transistor comprising a first collector and a first emitter, wherein the first output terminal corresponds to the first collector of the first transistor; and a second transistor comprising a second collector and a second emitter, wherein the second output terminal corresponds to the second collector of the second transistor.
Aspect 10: The apparatus of Aspect 9, wherein: the first emitter of the first transistor is coupled to the reference node; and the second emitter of the second transistor is coupled to the reference node.
Aspect 11: The apparatus according to any of Aspects 1-10, further comprising a transceiver comprising the amplifier.
Aspect 12: The apparatus of Aspect 11, wherein the transceiver comprises a transmit chain having the amplifier.
Aspect 13: The apparatus according to any of Aspects 1-12, wherein the amplifier comprises a linear power amplifier.
Aspect 14: A method for harmonic termination control of an amplifier, comprising: outputting an amplified differential signal via a first output terminal and a second output terminal of an amplifier; and controlling harmonic termination of the differential signal using a resonant circuit coupled between the first output terminal and the second output terminal of the amplifier, the resonant circuit comprising: a first capacitor having a first terminal and a second terminal, the first terminal of the first capacitor being coupled to the first output terminal of the amplifier, the second terminal of the first capacitor being coupled to a first node; a second capacitor having a third terminal and a fourth terminal, the third terminal of the second capacitor being coupled to the second output terminal of the amplifier, the fourth terminal of the second capacitor being coupled to a second node; a first inductor having a fifth terminal and a sixth terminal, the fifth terminal of the first inductor being coupled to the first node; a second inductor having a seventh terminal and an eighth terminal, the seventh terminal of the second inductor being coupled to the second node; and a third capacitor coupled between the first node and the second node.
Aspect 15: The method of Aspect 14, wherein controlling the harmonic termination comprises controlling an impedance of the resonant circuit at one or more harmonics in the differential signal using the resonant circuit.
Aspect 16: The method of Aspect 15, wherein the one or more harmonics comprise one or more of a second harmonic or a third harmonic.
Aspect 17: The method according to any of Aspects 14-16, wherein: the first capacitor has first capacitance value; the second capacitor has a second capacitance value; and the first capacitance value and the second capacitance value are within a threshold of one another.
Aspect 18: The method of Aspect 17, wherein the first capacitance value and the second capacitance value are tuned to control an impedance of the resonant circuit at a fundamental frequency associated with the differential signal.
Aspect 19: The method according to any of Aspects 14-18, wherein the third capacitor comprises a ninth terminal and a tenth terminal, the ninth terminal of the third capacitor being coupled to the first node, and the tenth terminal of the third capacitor being coupled to the second node.
Aspect 20: The method according to any of Aspects 14-19, wherein the third capacitor has a capacitance value tuned to control at least an impedance of the resonant circuit at a third harmonic associated with the differential signal.
Aspect 21: The method of Aspect 19 or 20, wherein: the fifth terminal of the first inductor is coupled to the ninth terminal of the third capacitor and the second terminal of the first capacitor; the sixth terminal of the first inductor is coupled to a reference node; the seventh terminal of the second inductor is coupled to the tenth terminal of the third capacitor and the fourth terminal of the second capacitor; and the eighth terminal of the second inductor is coupled to the reference node.
Aspect 22: The method of Aspect 21, wherein the amplifier comprises: a first transistor comprising a first collector and a first emitter, wherein the first output terminal corresponds to the first collector of the first transistor; and a second transistor comprising a second collector and a second emitter, wherein the second output terminal corresponds to the second collector of the second transistor.
Aspect 23: The method of Aspect 22, wherein: the first emitter of the first transistor is coupled to the reference node; and the second emitter of the second transistor is coupled to the reference node.
Aspect 24: The method according to any of Aspects 14-23, further comprising transmitting the amplified differential signal via a transceiver comprising the amplifier.
Aspect 25: The method of Aspect 24, wherein the transceiver comprises a transmit chain having the amplifier.
Aspect 26: The method according to any of Aspects 14-25, wherein the amplifier comprises a linear power amplifier.
Aspect 27: A transceiver, comprising: a transmit chain configured to output a radio frequency signal for transmission, wherein the transmit chain comprises: an amplifier configured to output a differential signal via a first output terminal and a second output terminal; and a resonant circuit coupled between the first output terminal and the second output terminal of the amplifier, wherein the resonant circuit comprises: a first capacitor having a first terminal and a second terminal, the first terminal of the first capacitor being coupled to the first output terminal of the amplifier, the second terminal of the first capacitor being coupled to a first node; a second capacitor having a third terminal and a fourth terminal, the third terminal of the second capacitor being coupled to the second output terminal of the amplifier, the fourth terminal of the second capacitor being coupled to a second node; a first inductor having a fifth terminal and a sixth terminal, the fifth terminal of the first inductor being coupled to the first node; a second inductor having a seventh terminal and an eighth terminal, the seventh terminal of the second inductor being coupled to the second node; and a third capacitor coupled between the first node and the second node.
Aspect 28: An apparatus, comprising means for performing a method in accordance with any of Aspects 14-26.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a microcontroller, a microprocessor, a general purpose processor, an artificial intelligence (AI) processor, a digital signal processor (DSP), an ASIC, a field programmable gate array (FPGA) or other programmable logic device (PLD), discrete gate or transistor logic, discrete hardware components, or any combination thereof designed to perform the functions described herein. A general purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), a system in package (SiP), or any other such configuration.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and or like. Also, “determining” may include receiving (e.g., receiving information), accessing (e.g., accessing data in a memory) or the like. Also, “determining” may include resolving, selecting, choosing, establishing or the like.

As used herein, “coupled to” and “coupled with” generally encompass direct coupling and indirect coupling (e.g., including intermediary coupled aspects) unless stated otherwise. For example, stating that a processor is coupled to a memory allows for a direct coupling or a coupling via an intermediary aspect, such as a bus.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Reference to an element in the singular is not intended to mean only one unless specifically so stated, but rather “one or more.” The subsequent use of a definite article (e.g., “the” or “said”) with an element (e.g., “the processor”) is not intended to invoke a singular meaning (e.g., “only one”) on the element unless otherwise specifically stated. For example, reference to an element (e.g., “a processor,” “a controller,” “a memory,” “a transceiver,” “an antenna,” “the processor,” “the controller,” “the memory,” “the transceiver,” “the antenna,” etc.), unless otherwise specifically stated, should be understood to refer to one or more elements (e.g., “one or more processors,” “one or more controllers,” “one or more memories,” “one more transceivers,” etc.). The terms “set” and “group” are intended to include one or more elements, and may be used interchangeably with “one or more.” Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions. Unless specifically stated otherwise, the term “some” refers to one or more. All structural and functional equivalents to the elements of the various aspects described throughout this disclosure that are known or later come to be known to those of ordinary skill in the art are intended to be encompassed by the claims. Moreover, nothing disclosed herein is intended to be dedicated to the public regardless of whether such disclosure is explicitly recited in the claims.

1. An apparatus configured for wireless communications, comprising:
an amplifier configured to output a differential signal via a first output terminal and a second output terminal; and
a resonant circuit coupled between the first output terminal and the second output terminal of the amplifier, the resonant circuit comprising:
a first capacitor having a first terminal and a second terminal, the first terminal of the first capacitor coupled to the first output terminal of the amplifier, the second terminal of the first capacitor coupled to a first node;
a second capacitor having a third terminal and a fourth terminal, the third terminal of the second capacitor coupled to the second output terminal of the amplifier, the fourth terminal of the second capacitor coupled to a second node;
a first inductor having a fifth terminal and a sixth terminal, the fifth terminal of the first inductor coupled to the first node;
a second inductor having a seventh terminal and an eighth terminal, the seventh terminal of the second inductor coupled to the second node; and
a third capacitor coupled between the first node and the second node.

2. The apparatus of claim 1, wherein the resonant circuit is configured to control an impedance of the resonant circuit at one or more harmonics in the differential signal.

3. The apparatus of claim 2, wherein the one or more harmonics comprise one or more of a second harmonic or a third harmonic.

4. The apparatus of claim 1, wherein:
the first capacitor has a first capacitance value;
the second capacitor has a second capacitance value; and
the first capacitance value and the second capacitance value are within a threshold of one another.

5. The apparatus of claim 4, wherein the first capacitance value and the second capacitance value are tuned to control an impedance of the resonant circuit at a fundamental frequency associated with the differential signal.

6. The apparatus of claim 1, wherein the third capacitor comprises a ninth terminal and a tenth terminal, the ninth terminal of the third capacitor coupled to the first node, and the tenth terminal of the third capacitor coupled to the second node.

7. The apparatus of claim 1, wherein the third capacitor has a capacitance value tuned to control at least an impedance of the resonant circuit at a third harmonic associated with the differential signal.

8. The apparatus of claim 6, wherein:
the fifth terminal of the first inductor is coupled to the ninth terminal of the third capacitor and the second terminal of the first capacitor;
the sixth terminal of the first inductor is coupled to a reference node;
the seventh terminal of the second inductor is coupled to the tenth terminal of the third capacitor and the fourth terminal of the second capacitor; and
the eighth terminal of the second inductor is coupled to the reference node.

9. The apparatus of claim 8, wherein the amplifier comprises:
a first transistor comprising a first collector and a first emitter, wherein the first output terminal corresponds to the first collector of the first transistor; and
a second transistor comprising a second collector and a second emitter, wherein the second output terminal corresponds to the second collector of the second transistor.

10. The apparatus of claim 9, wherein:
the first emitter of the first transistor is coupled to the reference node; and
the second emitter of the second transistor is coupled to the reference node.

11. The apparatus of claim 1, further comprising a transceiver comprising the amplifier.

12. The apparatus of claim 11, wherein the transceiver comprises a transmit chain having the amplifier.

13. The apparatus of claim 1, wherein the amplifier comprises a linear power amplifier.

14. A transceiver, comprising:
a transmit chain configured to output a radio frequency signal for transmission, wherein the transmit chain comprises: an amplifier configured to output a differential signal via a first output terminal and a second output terminal; and a resonant circuit coupled between the first output terminal and the second output terminal of the amplifier, wherein the resonant circuit comprises:
a first capacitor having a first terminal and a second terminal, the first terminal of the first capacitor coupled to the first output terminal of the amplifier, the second terminal of the first capacitor coupled to a first node;
a second capacitor having a third terminal and a fourth terminal, the third terminal of the second capacitor coupled to the second output terminal of the amplifier, the fourth terminal of the second capacitor coupled to a second node;
a first inductor having a fifth terminal and a sixth terminal, the fifth terminal of the first inductor coupled to the first node;
a second inductor having a seventh terminal and an eighth terminal, the seventh terminal of the second inductor coupled to the second node; and
a third capacitor coupled between the first node and the second node.

15. A method for harmonic termination control of an amplifier, comprising:
outputting an amplified differential signal via a first output terminal and a second output terminal of an amplifier; and
controlling harmonic termination of the differential signal using a resonant circuit coupled between the first output terminal and the second output terminal of the amplifier, the resonant circuit comprising:
a first capacitor having a first terminal and a second terminal, the first terminal of the first capacitor coupled to the first output terminal of the amplifier, the second terminal of the first capacitor coupled to a first node;
a second capacitor having a third terminal and a fourth terminal, the third terminal of the second capacitor coupled to the second output terminal of the amplifier, the fourth terminal of the second capacitor coupled to a second node;
a first inductor having a fifth terminal and a sixth terminal, the fifth terminal of the first inductor coupled to the first node;
a second inductor having a seventh terminal and an eighth terminal, the seventh terminal of the second inductor coupled to the second node; and
a third capacitor coupled between the first node and the second node.

16. The method of claim 15, wherein controlling the harmonic termination comprises controlling an impedance of the resonant circuit at one or more harmonics in the differential signal using the resonant circuit.

17. The method of claim 16, wherein the one or more harmonics comprise one or more of a second harmonic or a third harmonic.

18. The method of claim 15, further comprising transmitting a signal, based on the amplified differential signal, via a transceiver comprising the amplifier.

19. The method of claim 18, wherein the transceiver comprises a transmit chain having the amplifier.

20. The method of claim 15, wherein the amplifier comprises a linear power amplifier.
